(19) United States
(12) Patent Application Publication
(10) Pub. No.: US 2021/0057597 A1
(43) Pub. Date: Feb. 25, 2021

(54) METHOD FOR MANUFACTURING SOLAR CELL, AND HOLDER USED FOR SAME

(71) Applicant: KANEKA CORPORATION, Osaka (JP)

(72) Inventors: Kunihiro NAKANO, Osaka (JP); Ryota MISHIMA, Osaka (JP); Katsunori KONISHI, Osaka (JP); Takashi KUCHIYAMA, Osaka (JP)

(73) Assignee: KANEKA CORPORATION, Osaka (JP)

(21) Appl. No.: 17/090,350

(22) Filed: Nov. 5, 2020

Related U.S. Application Data
(63) Continuation of application No. PCT/JP2019/018395, filed on May 8, 2019.

(30) Foreign Application Priority Data
May 8, 2018 (JP) 2018-089819

(51) Int. Cl. H01L 31/0747; H01L 31/0224; H01L 31/0236; H01L 31/18

(52) U.S. Cl. CPC H01L 31/0747; H01L 31/022441; H01L 31/1888; H01L 31/022466; H01L 31/02366

(57) ABSTRACT

A method for manufacturing a solar cell includes: forming a first semiconductor layer of a first conductivity type on and over one of two major surfaces facing each other on a crystal substrate; forming a lift-off layer on and over the first semiconductor layer; selectively removing the lift-off layer and first semiconductor layer; forming a second semiconductor layer of a second conductivity type on and over the major surface having the lift-off layer and the first semiconductor layer; and removing the second semiconductor layer covering the lift-off layer by removing the lift-off layer using an etching solution; and washing the crystal substrate by using a rinsing liquid. A contact angle of the etching solution or the rinsing liquid relative to the lift-off layer is smaller than a contact angle of the etching solution or the rinsing liquid relative to the second semiconductor layer, and the contact angle of the etching solution or the rinsing liquid relative to the second semiconductor layer is 65° or more to 110° or less.

### CROSS-REFERENCE TO RELATED APPLICATIONS

This is a continuation of International Application No. PCT/JP201918395 filed on May 8, 2019, which claims priority to Japanese Patent Application No. 2018-089819 filed on May 8, 2018. The entire disclosures of these applications are incorporated by reference herein.

### BACKGROUND

The present disclosure relates to a method for manufacturing a solar cell and a holder used for the same.

Typically, a double-sided electrode type solar cell in which electrodes are disposed on both surfaces (a light-receiving surface and a back surface) of a semiconductor substrate has been used as a solar cell. Further, in recent years, a back-contact (back-electrode) type solar cell in which an electrode is disposed only on the back surface as shown in Japanese Unexamined Patent Publication No. 2013-120863 has been developed as a solar cell without shadow loss caused by the electrode.

In the back-contact type solar cell, a semiconductor layer such as a p-type semiconductor layer and an n-type semiconductor layer on the back surface has to be patterned with high accuracy. Thus, manufacturing a back-contact type solar cell is more complicated than manufacturing a double-sided electrode type solar cell. Japanese Unexamined Patent Publication No. 2013-120863 presents a technique for patterning a semiconductor layer by a lift-off method as a technique for simplifying the method for manufacturing a solar cell. That means, the development of a technique of patterning a semiconductor layer through removing a lift-off layer to selectively remove the semiconductor layer formed on the lift-off layer.

### SUMMARY

However, in the technique of Japanese Unexamined Patent Publication No. 2013-120863, if the solubility of the lift-off layer is close to that of the semiconductor layer, an unintended layer may be removed. This may result in a reduction in patterning accuracy or productivity.

Further, dissolving the lift-off layer in the lift-off step may cause the semiconductor layer and other layers which have been formed on the lift-off layer to get separated and float in a liquid or on a surface of the liquid used in the step and to reattach to the substrate. This has been a cause of a decrease in the productivity and yield.

The present disclosure has been made in view of the above, and an object thereof is to efficiently manufacture a high-performance, back-contact type solar cell.

In order to achieve the object, a first aspect of the present disclosure is directed to a method for manufacturing a solar cell, the method including: forming a first semiconductor layer of a first conductivity type on one of two major surfaces of a semiconductor substrate, the two major surfaces facing each other; forming a lift-off layer on the first semiconductor layer; selectively removing the lift-off layer and first semiconductor layer; forming a second semiconductor layer of a second conductivity type on the major surface including the lift-off layer and the first semiconductor layer; removing the second semiconductor layer covering the lift-off layer by removing the lift-off layer using an etching solution; and washing the semiconductor substrate by using a rinsing liquid; wherein a contact angle of the etching solution or the rinsing liquid relative to the lift-off layer is smaller than a contact angle of the etching solution or the rinsing liquid relative to the second semiconductor layer, and the contact angle of the etching solution or the rinsing liquid relative to the second semiconductor layer is 65° or more to 110° or less.

The present disclosure can efficiently manufacture a high-performance, back-contact type solar cell with improved productivity and yield.

### BRIEF DESCRIPTION OF THE DRAWINGS

FIG. 1 is a schematic cross-sectional view partially illustrating a solar cell according to a first embodiment.

FIG. 2 is a top view illustrating a backside major surface of a crystal substrate constituting the solar cell according to the first embodiment.

FIG. 3 is a schematic cross-sectional view partially illustrating one step of a method for manufacturing the solar cell according to the first embodiment.

FIG. 4 is a schematic cross-sectional view partially illustrating one step of the method for manufacturing the solar cell according to the first embodiment.

FIG. 5 is a schematic cross-sectional view partially illustrating one step of the method for manufacturing the solar cell according to the first embodiment.

FIG. 6 is a schematic cross-sectional view partially illustrating one step of the method for manufacturing the solar cell according to the first embodiment.

FIG. 7 is a schematic cross-sectional view partially illustrating one step of the method for manufacturing the solar cell according to the first embodiment.

FIG. 8 is a schematic cross-sectional view partially illustrating one step of the method for manufacturing the solar cell according to the first embodiment.

FIG. 9 is a schematic cross-sectional view partially illustrating one step of the method for manufacturing the solar cell according to the first embodiment.

FIG. 10 is a perspective view illustrating a substrate holder according to a second embodiment.

FIG. 11 is a top view illustrating a support for supporting a substrate in a substrate holder according to the second embodiment.

FIG. 12 is a cross-sectional view taken along line XII-XII of FIG. 11.

### DETAILED DESCRIPTION

Hereinafter, exemplary embodiments of the present disclosure will be described in detail with reference to the drawings. Note that the embodiments described below are merely preferred examples in nature, and are not intended to limit the applications or use of the present disclosure. The dimensional ratio of each component in the drawings is shown for the sake of convenience in illustration and is not necessarily the same as the actual one.

### First Embodiment

A first embodiment of the present disclosure will be described with reference to the drawings.

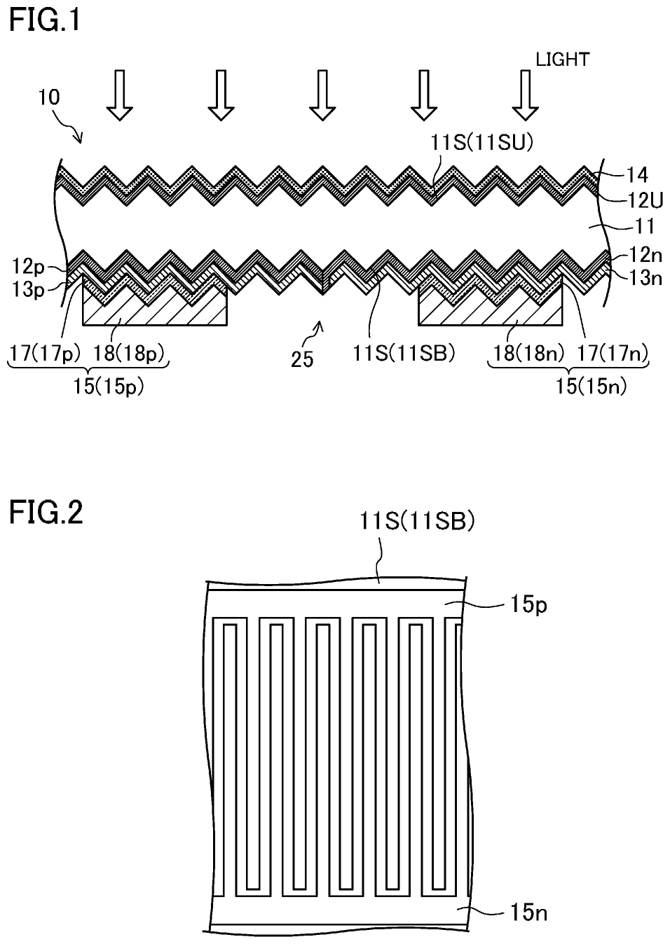

FIG. 1 is a cross-sectional view partially illustrating a solar cell (cell) according to this embodiment. As shown in FIG. 1, a solar cell 10 according to this embodiment uses a crystal substrate 11 made of silicon (Si). The crystal substrate 11 has two major surfaces 11S (11SU, 11SB) facing each other. The major surface that receives light is referred to as a frontside major surface 11SU, and the opposite major surface is referred to as a backside major surface 11SB. Note that the frontside major surface 11SU is a light-receiving side made to receive light more actively than the backside major surface 11SB. Thus, for the sake of convenience, the frontside major surface 11SU is also referred to as a light-receiving side. Further, for the sake of convenience, the backside major surface 11SB is also referred to as a back surface side.

The solar cell 10 according to this embodiment is a so-called heterojunction crystal silicon solar cell and is of a back-contact type (back-electrode type) in which an electrode layer is disposed on the backside major surface 11SB.

The solar cell 10 includes a crystal substrate 11, an intrinsic semiconductor layer 12, a conductivity type semiconductor layer 13 (a p-type semiconductor layer 13p, an n-type semiconductor layer 13n), a low reflection layer 14, and an electrode layer 15 (a transparent electrode layer 17, a metal electrode layer 18).

For the sake of convenience, the respective reference characters of members, corresponding to the p-type semiconductor layer 13p and the n-type semiconductor layer 13n, are also assigned with the suffixes “p” and “n.” Further, one of the p-type and the n-type is also referred to as a “first conductivity type”, and the other conductivity type may be referred to as a “second conductivity type.”

The crystal substrate 11 may be formed of single crystal silicon or polycrystal silicon. Hereinafter, a single crystal silicon substrate will be described as an example.

The crystal substrate 11 may be an n-type single crystal silicon substrate doped with an impurity (e.g., a phosphorus (P) atom) for introducing electrons into silicon atoms or a p-type silicon substrate doped with an impurity (e.g., boron (B) atom) for introducing positive holes into silicon atoms. Hereinafter, an n-type single crystal silicon substrate that is said to have a long carrier lifetime will be described as an example.

From the viewpoint of confining received light, the two major surfaces 11S of the crystal substrate 11 may have a texture structure TX (first texture structure) formed of mountains (projections) and valleys (depressions). The texture structure TX (uneven surface) can be formed by, for example, anisotropic etching with application of the difference between an etching rate for the (100) plane and that for the (111) plane in the crystal substrate 11.

The size of the projections and depressions in the texture structure TX can be defined by the number of vertexes of the projections. In this embodiment, from the viewpoint of light collection performance and productivity, the number of vertexes is preferably in the range from 50000 vertexes/mm² or more to 100000 vertexes/mm² or less, more preferably from 70000 vertexes/mm² or more to 85000 vertexes/mm² or less.

The thickness of the crystal substrate 11 may be 250 μm or less. The thickness is measured in the direction perpendicular to the average surface of the crystal substrate 11 (which means the surface of an overall substrate not depending on the texture structure TX).

If the thickness of the crystal substrate 11 is 250 μm or less, the amount of silicon used is reduced, which makes it easy to secure the silicon substrate and allows a cost reduction. In addition, the back-contact structure for collecting, only on the back surface side, positive holes and electrons generated by photo-excitation within the silicon substrate is suitable from the viewpoint of a free path of each exciton.

An excessively thin crystal substrate 11 causes a reduction in mechanical strength, insufficient absorption of external light (sunlight), and a reduction in short circuit current density. Thus, the thickness of the crystal substrate 11 is preferably 50 μm or more, more preferably 70 μm or more. In the case in which the major surface of the crystal substrate 11 has a texture structure TX, the thickness of the crystal substrate 11 is represented by a distance between straight lines each connecting vertexes of projections in the uneven structure on each of the light-receiving side and the back surface side.

The intrinsic semiconductor layer 12 (12U, 12p, 12n) covers both major surfaces 11S (11SU, 11SB) of the crystal substrate 11, thereby performing surface passivation while avoiding impurities from diffusing into the crystal substrate 11. Note that the “intrinsic (i-type)” semiconductor layer is not limited to a completely intrinsic semiconductor layer containing no conductive impurity, and encompasses a substantially intrinsic layer of “weak n-type” or “weak p-type” containing a trace amount of an n-type impurity or a p-type impurity within the range in which the silicon-based layer can function as an intrinsic layer.

The material for the intrinsic semiconductor layer 12 is not particularly limited, but may be an amorphous silicon thin layer, and may be a hydrogenated amorphous silicon-based thin layer (a-Si:H thin film) containing silicon and hydrogen. Being amorphous described herein means a structure lacking a long-range order, i.e., encompasses not only a structure having complete disorder, but also a short-range order. Further, note that the intrinsic semiconductor layer 12 (12U, 12p, 12n) is not an essential component and may be appropriately formed, as required.

The thickness of the intrinsic semiconductor layer 12 is not particularly limited and may be 2 nm or more to 20 nm or less. This is because the intrinsic semiconductor layer 12 having a thickness of 2 nm or more enhances an effect as a passivation layer for the crystal substrate 11, and the one having a thickness of 20 nm or less avoids a decrease in conversion characteristic caused by an increase in resistance.

The intrinsic semiconductor layer 12 can be formed by any method without particular limitations, but may be formed by a plasma enhanced chemical vapor deposition (plasma-enhanced CVD) method. This method allows effective passivation on the surface of the substrate while avoiding impurities from diffusing into single crystal silicon. The plasma-enhanced CVD method also allows formation of an energy gap profile effective for collecting carriers by varying the hydrogen concentration within the intrinsic semiconductor layer 12 along the thickness direction.

Film-forming conditions for a thin film by the plasma-enhanced CVD method may be the substrate temperature of 100° C. or more to 300° C. or less, the pressure of 20 Pa or more to 2600 Pa or less, the high-frequency power density of 0.003 W/cm² or more to 0.5 W/cm² or less.

The raw material gas used for the formation of a thin film as the intrinsic semiconductor layer 12 may be a silicon-containing gas such as monosilane (SiH₄) or disilane (Si₂H₆), or a mixed gas of the silicon-containing gas and hydrogen (H₂).

The energy gap of the thin film can be changed, as appropriate, by adding, to the raw material gas, a gas containing different species of elements, such as methane (CH₄), ammonia (NH₃), and monogermane (GeH₄) to form a silicon-based compound such as silicon carbide (SiC), silicon nitride (SiNₓ), and silicon germanium (SiGe).

The conductivity type semiconductor layer 13 includes the p-type semiconductor layer 13p and the n-type semiconductor layer 13n. As shown in FIG. 1, the p-type semiconductor layer 13p is formed over a part of the backside major surface 11SB of the crystal substrate 11 via the intrinsic semiconductor layer 12p. The n-type semiconductor layer 13n is formed over the other part of the backside major surface of the crystal substrate 11 via the intrinsic semiconductor layer 12n. Specifically, the intrinsic semiconductor layer 12 is interposed, as an intermediate layer for passivation, between the p-type semiconductor layer 13p and the crystal substrate 11 and between the n-type semiconductor layer 13n and the crystal substrate 11.

The thickness of each of the p-type semiconductor layer 13p and the n-type semiconductor layer 13n is not particularly limited and may be 2 nm or more to 20 nm or less. This is because the intrinsic semiconductor layer 12 having a thickness of 2 nm or more enhances an effect as a passivation layer, and the one having a thickness of 20 nm or less avoids a decrease in conversion characteristic caused by an increase in resistance.

The p-type semiconductor layer 13p and the n-type semiconductor layer 13n are disposed over the backside major surface 11SB of the crystal substrate 11 so as to be electrically disconnected from each other via the intrinsic semiconductor layer 12. The width of the conductivity type semiconductor layer 13 may be 50 μm or more to 3000 μm or less, or may be 80 μm or more to 500 μm or less. Note that the width of the semiconductor layer 12, 13 and the widths of the electrode layers 17, 18 mean the lengths of the parts of the respective patterned layers in a direction parallel to the average surface of the crystal substrate 11, and means, for example, lengths in a direction orthogonal to the direction in which linear parts of the respective layers extend, unless otherwise stated.

If photo excitons (carriers) generated in the crystal substrate 11 are taken out via the conductivity type semiconductor layer 13, the effective mass of the positive holes is larger than that of the electrons. Thus, from the viewpoint of reducing a transport loss, the p-type semiconductor layer 13p may be narrower than the n-type semiconductor layer 13n. For example, the width of the p-type semiconductor layer 13p may be 0.5 times or more to 0.9 times or less, preferably 0.6 times or more to 0.8 times or less that of the n-type semiconductor layer 13n.

The p-type semiconductor layer 13p is a silicon layer doped with a p-type dopant (such as boron), and may be formed of amorphous silicon from the viewpoint of avoiding diffusion of impurities and reducing series resistance. The n-type semiconductor layer 13n is a silicon layer doped with an n-type dopant (such as phosphorus), and may be an amorphous silicon layer as in the p-type semiconductor layer 13p.

The raw material gas used for the formation of the conductivity type semiconductor layer 13 may be a silicon-containing gas such as monosilane (SiH₄) or disilane (Si₂H₆), or a mixed gas of the silicon-containing gas and hydrogen (H₂). Diborane (B₂H₆) can be used as a dopant gas for the formation of p-type semiconductor layer 13p, and phosphine (PH₃) can be used as a dopant gas for the formation of the n-type semiconductor layer 13n. A trace amount of boron (B) or phosphorus (O) is only required to be added as an impurity, and thus, a mixed gas obtained by diluting the dopant gas with the raw material gas may be used.

In order to adjust the energy gap of the p-type semiconductor layer 13p or the n-type semiconductor layer 13n, the p-type semiconductor layer 13p or the n-type semiconductor layer 13n may be formed into a compound by adding a gas containing different species of elements, such as methane (CH₄), carbon dioxide (CO₂), ammonia (NH₃), and monogermane (GeH₄).

The low reflection layer 14 reduces reflection of light received by the solar cell 10. The material for the low reflection layer 14 may be any translucent material which transmits light without particular limitations, and examples thereof include silicon oxide (SiOₓ), silicon nitride (SiNₓ), zinc oxide (ZnO), and titanium oxide (TiOₓ). The low reflection layer 14 may be formed by, for example, sputtering method and application of a resin material containing nanoparticles of oxide such as zinc oxide and titanium oxide, dispersed therein.

The electrode layer 15 is formed to cover each of the p-type semiconductor layer 13p and the n-type semiconductor layer 13n, thereby being electrically connected to the conductivity type semiconductor layer 13. Thus, the electrode layer 15 functions as a transport layer for guiding carriers generated in each of the p-type semiconductor layer 13p and the n-type semiconductor layer 13n. The electrode layer 15p corresponding to the semiconductor layer 13p and the electrode layer 15n corresponding to the semiconductor layer 13n are separated from each other so as to avoid a short circuit between the p-type semiconductor layer 13p and the n-type semiconductor layer 13n.

From the viewpoint of electrical junction with each of the p-type semiconductor layer 13p and the n-type semiconductor layer 13n, or from the viewpoint of preventing atoms of a metal which is an electrode material from diffusing in both of the semiconductor layers 13p and 13n, the electrode layer 15 formed of a transparent conductive oxide may be provided between an electrode layer formed of a metal and the p-type semiconductor layer 13p and between an electrode layer formed of a metal and the n-type semiconductor layer 13n.

In this embodiment, the electrode layer 15 formed of a transparent conductive oxide is referred to as the transparent electrode layer 17, and the electrode layer 15 formed of a metal is referred to as the metal electrode layer 18. As shown in the plan view of the backside major surface 11SB of the crystal substrate 11 of FIG. 2, in the p-type semiconductor layer 13p and the n-type semiconductor layer 13n each having a comb-tooth shape, an electrode layer formed on a base portion of the comb is also referred to as a busbar portion, and an electrode layer formed on a teeth portion of the comb is also referred to as a finger portion.

The material for the transparent electrode layer 17 is not particularly limited, and examples thereof include zinc oxide (ZnO), indium oxide (InOₓ), and transparent conductive oxides obtained by adding, to indium oxide, various metal oxides such as titanium oxide (TiOₓ), tin oxide (SnOₓ), tungsten oxide (WOₓ), and molybdenum oxide (MoOₓ) at a concentration of 1 wt % or more to 10 wt % or less.

The thickness of the transparent electrode layer 17 may be 20 nm or more to 200 nm or less. A transparent electrode layer suitable for this thickness may be formed by, for example, the physical vapor deposition (PVD) method such as a sputtering method, or the metal-organic chemical vapor deposition (MOCVD) method utilizing a reaction of an organic metal compound with oxygen or water.

The material for the metal electrode layer 18 is not particularly limited, and examples thereof include silver (Ag), copper (Cu), aluminum (Al), and nickel (Ni).

The thickness of the metal electrode layer 18 may be 1 μm or more to 80 μm or less. The metal electrode layer 18 suitable for this thickness may be formed by a printing method such as ink-jet printing or screen printing of a material paste, or by a plating method. However, the present disclosure is not limited thereto, and if a vacuum process is employed, a vapor deposition or sputtering method may be employed.

The width of the teeth portion of the comb in each of the p-type semiconductor layer 13p and the n-type semiconductor layer 13n may be the same as that of the metal electrode layer 18 formed on the teeth portion. Note that the width of the metal electrode layer 18 may be narrower than that of the teeth portion. With the configuration in which the occurrence of leakage between the metal electrode layers 18 is avoided, the metal electrode layer 18 may be wider than the teeth portion.

In this embodiment, an intrinsic semiconductor layer 12, a conductivity type semiconductor layer 13, and an electrode layer 15 are stacked on the backside major surface 11SB of a crystal substrate 11, and a predetermined annealing is performed with the intrinsic semiconductor layer 12 and a low reflection layer 14 being stacked on the frontside major surface 11SU of the crystal substrate 11, to perform passivation at each junction surface, avoid generation of a defect level at the conductivity type semiconductor layer 13 and its interfaces, and crystallize the transparent conductive oxide in the transparent electrode layers 17.

The annealing according to this embodiment may be performed by placing the crystal substrate 11 having the layers formed in a heated oven at a temperature of 150° C. or more to 200° C. or less. In this case, the atmosphere in the oven may be atmospheric air, and the annealing can be performed more effectively using hydrogen or nitrogen. The annealing may be performed also by rapid thermal annealing (RTA) of irradiating the crystal substrate 11 having the formed layers, with infrared light using an infrared heater.

Method for Manufacturing Solar Cell

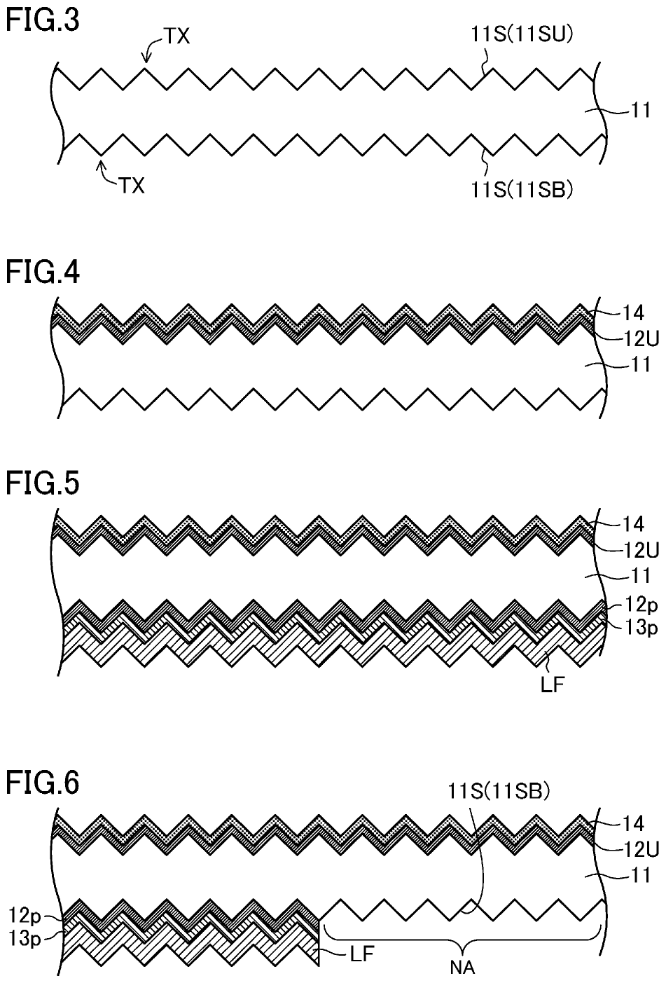

A method for manufacturing the solar cell 10 according to this embodiment will be described below with reference to FIGS. 3 to 9.

First, as shown in FIG. 3, a crystal substrate 11 having a frontside major surface 11SU and a backside major surface 11SB both of which have a texture structure TX is prepared.

Next, as shown in FIG. 4, for example, an intrinsic semiconductor layer 12U is formed on the frontside major surface 11SU of the crystal substrate 11. Subsequently, a low reflection layer 14 is formed on the formed intrinsic semiconductor layer 12U. The low reflection layer 14 uses silicon nitride (SiNₓ) or silicon oxide (SiOₓ) having a suitable light absorption coefficient and refractive index from the viewpoint of confining incident light.

Then, as shown in FIG. 5, for example, an intrinsic semiconductor layer 12p using, for example, an i-type amorphous silicon is formed on the backside major surface 11SB of the crystal substrate 11. Further, a p-type semiconductor layer 13p is formed on the intrinsic semiconductor layer 12p formed. Thus, the p-type semiconductor layer 13p is formed over the backside major surface 11SB which is one of the major surfaces of the crystal substrate 11. Thus, in this embodiment, the forming of the p-type semiconductor layer (first semiconductor layer) 13p includes forming an intrinsic semiconductor layer (first intrinsic semiconductor layer) 12p on one major surface (backside major surface) 11S of the crystal substrate (semiconductor substrate) 11 prior to the forming of the p-type semiconductor layer 13p.

Then, a lift-off layer LF is formed on the formed p-type semiconductor layer 13p. Specifically, the lift-off layer LF containing silicon oxide (SiOₓ) as a main component is formed on the p-type semiconductor layer 13p.

Subsequently, as shown in FIG. 6, the lift-off layer LF and the p-type semiconductor layer 13p over the backside major surface 11SB of the crystal substrate 11 are patterned. In this way, the p-type semiconductor layer 13p is selectively removed, thereby generating a non-formed area NA where the p-type semiconductor layer 13p is not formed. On the other hand, in an area which has not been etched on or over the backside major surface 11SB of the crystal substrate 11, at least the lift-off layer LF and p-type semiconductor layer 13p remain.

Such patterning is achieved by photolithography, i.e., for example, forming a resist film (not shown) having a predetermined pattern on the lift-off layer LF and etching a region masked with the resist film formed. As shown in FIG. 6, the intrinsic semiconductor layer 12p, the p-type semiconductor layer 13p, and the lift-off layer LF are patterned, thereby generating the non-formed area NA in a part of the backside major surface 11SB of the crystal substrate 11, i.e., an area where the backside major surface 11B is exposed. The non-formed area NA will be described later.

An etching solution used in the step shown in FIG. 6 can be a mixed solution (e.g., hydrofluoric nitric acid) of hydrofluoric acid and an oxidizing solution or a solution (hereinafter, ozone-hydrofluoric acid solution) obtained by dissolving ozone in hydrofluoric acid. An etching agent that contributes to etching of the lift-off layer LF is hydrogen fluoride. The patterning described herein is not limited to wet etching using the etching solution. The patterning may be, for example, performed by dry etching or pattern printing using an etching paste or the like.

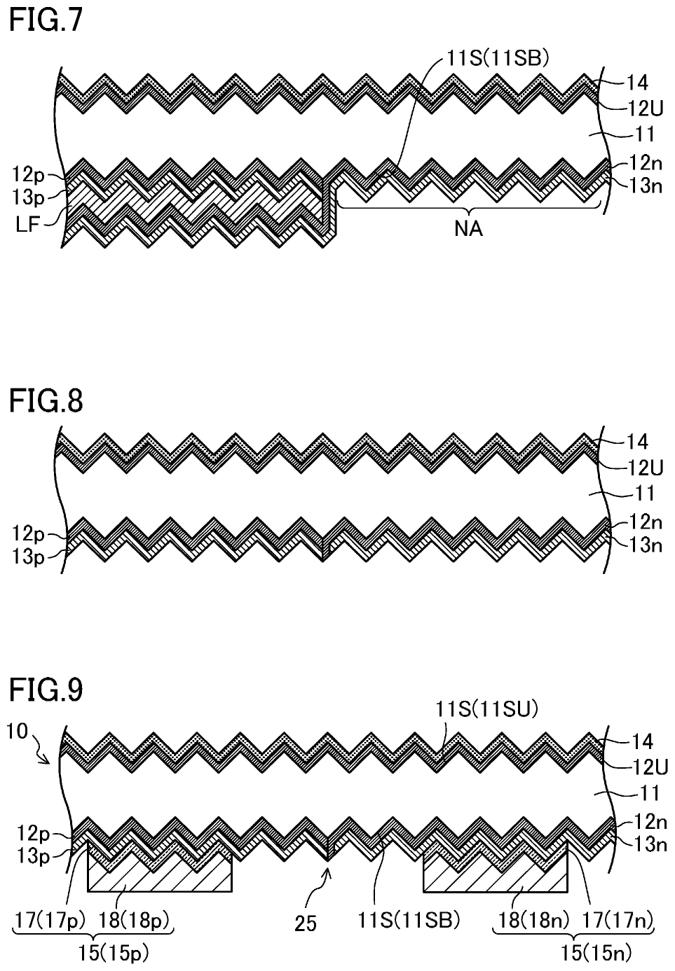

Next, as shown in FIG. 7, an intrinsic semiconductor layer 12n and an n-type semiconductor layer 13n are formed in this order on and over the backside major surface 11SB of the crystal substrate 11 having the lift-off layer LF, the p-type semiconductor layer 13p, and the intrinsic semiconductor layer 12p. Thus, in this embodiment, the forming of the n-type semiconductor layer (second semiconductor layer) 13n includes forming an intrinsic semiconductor layer (second intrinsic semiconductor layer) 12n on and over one major surface (backside major surface) 11S of the crystal substrate (semiconductor substrate) 11 having the lift-off layer LF and the p-type semiconductor layer prior to the forming of the n-type semiconductor layer 13n. Thus, a laminate film of the intrinsic semiconductor layer 12n and the n-type semiconductor layer 13n is formed on the non-formed area NA, the surface and side surface (end surface) of the lift-off layer LF, and the side surfaces (end surfaces) of the p-type semiconductor layer 13p and the intrinsic semiconductor layer 12p.

Next, as shown in FIG. 8, the lift-off layer LF is removed using the etching solution, and thus the n-type semiconductor layer 13n and the intrinsic semiconductor layer 12n covering the lift-off layer LF are removed from the crystal substrate 11 (this step will be referred to as a “lift-off step”). The etching solution used in this lift-off step may be, for example, a solution containing hydrofluoric acid as a main component.

Thereafter, the etching solution in contact with the crystal substrate 11 is removed by using a rinsing liquid (this step will be referred to as a “rinsing step”). Note that the n-type semiconductor layer 13n and the intrinsic semiconductor layer 12n covering the lift-off layer, which could not be completely removed in the lift-off step, are removed in the rinsing step.

The surface tension of the etching solution used in the lift-off step and the surface tension of the rinsing liquid used in the rinsing step are preferably 25 mN/m or more to 70 mN/m or less, particularly preferably 30 mN/m or more to 60 mN/m or less. When the surface tension is within this range, the wettability to the p-type semiconductor layer 13p and the lift-off layer LF becomes high, and the lift-off step proceeds smoothly. Further, particles of the n-type semiconductor layer 13n and the intrinsic semiconductor layer 12n that have peeled off in the lift-off step and the rinsing step easily aggregate in the etching solution and the rinsing liquid. The particles increase in size by the aggregation, which avoids the n-type semiconductor layer 13n and the intrinsic semiconductor layer 12n from reattaching to the crystal substrate 11. In addition, the particles are easily removed by filtering while the etching solution or the rinsing liquid is circulated. In this manner, fine peeled-off and floating particles do not remain in the liquid for a long period of time, which improves the productivity and yield.

The surface tension of the etching solution and the surface tension of the rinsing liquid can be adjusted by using a lower alcohol or inorganic salt as a liquidity adjusting agent. For example, the surface tension is increased by adding an appropriate amount of an aqueous inorganic salt solution, and is decreased by adding an appropriate amount of the lower alcohol. As the inorganic salt, a liquidity adjusting agent that easily dissociates (ionizes) in a solution of sodium chloride or potassium chloride in water is used. As the lower alcohol, a liquidity adjusting agent having a high polarity such as ethanol or propanol is selected. The surface tension may be reduced by a known method of adding a surfactant such as an ammonium compound. However, the lower alcohol enables to remove hydrogen generating from the surface of the crystal substrate 11 during the etching process, thereby making it possible to uniformly etch the surface of the crystal substrate 11.

For example, regarding addition of the liquidity adjusting agent, a dynamic surface tensiometer is placed in a process liquid, and the aqueous inorganic salt solution is added if the surface tension goes below the previously set surface tension, and the lower alcohol is added if the surface tension exceeds the previously set surface tension. In this manner of this process, the liquid can be appropriately adjusted. This allows a decrease in productivity and yield caused by the surface tension deviating from the predetermined value to be avoided.

It is further preferred that, in at least one of the lift-off step or the rinsing step, the semiconductor substrate is brought into contact with the etching solution or the rinsing liquid with being inclined relative to the liquid surface. Hereinafter, bringing the semiconductor substrate into contact with the liquid surface of the etching solution or the rinsing liquid with the semiconductor substrate being inclined relative to the liquid surface will be referred to as a “inclination contact.” Specifically, the rinsing step is more effective when the semiconductor substrate is brought into contact with the rinsing liquid with being inclined. Although the reason of this is unknown in detail, it is considered to be due to the fact that the inclination contact makes the n-type semiconductor layer 13n and the intrinsic semiconductor layer 12n that have peeled off easily float in the liquid without reattaching to the semiconductor substrate. In particular, it has been confirmed that when at least the backside major surface 11SB of the two major surfaces 11SU and 11SB of the semiconductor substrate has a texture shape, the etching solution or the rinsing liquid easily enter between the p-type semiconductor layer 13p and the intrinsic semiconductor layer 12n (or the lift-off layer LF) formed on or over the back main surface 11SB. From this viewpoint, the semiconductor substrate according to this embodiment preferably is brought into contact with the liquid with the semiconductor layer facing upward.

An angle between the surface of the liquid and the semiconductor substrate, that is, an inclination angle of the average surface of the semiconductor substrate relative to the liquid surface is preferably 30° or more to 70° or less, particularly preferably 40° or more to 65° or less. The semiconductor substrate according to this embodiment is single crystal silicon. If the surface of the single crystal silicon has the texture shape as described above, the angle between the semiconductor substrate and the texture-shaped surface is about 50° or more to about 55° or less. Therefore, the etching solution or the rinsing liquid is more likely to be penetrated into the interface between the p-type semiconductor layer 13p and the lift-off layer LF formed over the semiconductor substrate when the semiconductor substrate having a texture shape of this angle is brought into inclination contact with the etching solution or the rinsing liquid. This facilitates peeling off of the n-type semiconductor layer 13n and the intrinsic semiconductor layer 12n from the semiconductor substrate. At the same time, the n-type semiconductor layer 13n and the intrinsic semiconductor layer 12n that have peeled off from the semiconductor substrate easily float in the liquid without contact with the original semiconductor substrate. At this time, in this embodiment, wettability of at least one of the etching solution or the rinsing liquid is adjusted to be high particularly to the lift-off layer LF, and to be low to the n-type semiconductor layer 13n and the intrinsic semiconductor layer 12n that have peeled off. Thus, the particles of the separated n-type semiconductor layer 13n and the intrinsic semiconductor layer 12n are more likely to aggregate. This avoids the n-type semiconductor layer 13n and the intrinsic semiconductor layer 12n that have peeled off from reattaching to the crystal substrate 11.

Therefore, the etching solution or the rinsing liquid according to this embodiment is adjusted to have a contact angle relative to the lift-off layer LF smaller than the contact angle relative to the n-type semiconductor layer 13n, and preferably smaller than the contact angles relative to the p-type semiconductor layer 13p, n-type semiconductor layer 13n, and the intrinsic semiconductor layers 12p, 12n. This adjustment accelerates penetration of the liquid into the interface between the lift-off layer LF and the n-type semiconductor layer 13n, preferably the interface between the lift-off layer LF and the other layer, thereby accelerating peeling off of the lift-off layer LF.

When the contact angle of the rinsing liquid or the etching solution relative to the p-type semiconductor layer 13p is represented by θ1, and the contact angle of the rinsing liquid or the etching solution relative to the n-type semiconductor layer 13n is represented by θ2, the relational expression 01<02 is satisfied. That is, the contact angle of the rinsing liquid or the etching solution relative to the p-type semiconductor layer 13p, and the contact angle of the rinsing liquid or the etching solution relative to the lift-off layer LF are both smaller than the contact angle of the rinsing liquid or the etching solution relative to the n-type semiconductor layer 13n. This avoids penetration of the liquid toward the n-type semiconductor layer 13n and accelerates penetration of the liquid into the interface between the lift-off layer LF and the p-type semiconductor layer 13p when the p-type semiconductor layer 13p is exposed at a portion which has been subjected to the lift-off during the lift-off step.

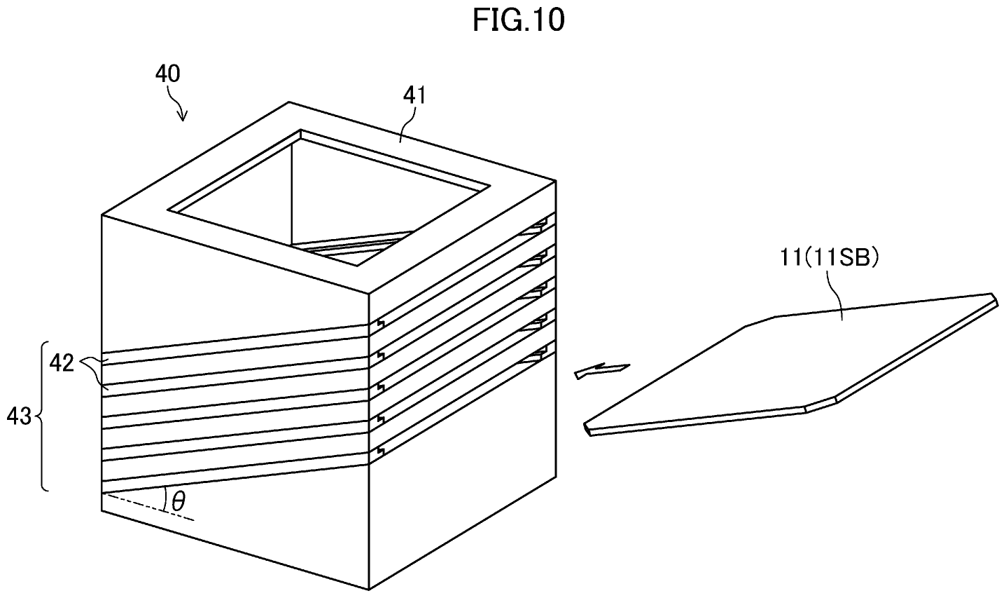

Then, as shown in FIG. 9, a transparent electrode layer 17 (17p, 17n) is formed over the backside major surface 11SB of the crystal substrate 11, i.e., on each of the p-type semiconductor layer 13p and the n-type semiconductor layer 13n by sputtering using a mask, to form a separation trench 25. The transparent electrode layer 17 (17p, 17n) may be formed by the following method as a substitute for the sputtering. For example, the transparent electrode layer 17 (17p, 17n) may be formed by forming a transparent conductive oxide film over the entire backside major surface 11SB without a mask and thereafter etching by photolithography to leave the transparent conductive oxide film on each of the p-type semiconductor layer 13p and the n-type semiconductor layer 13n. Then, a separation trench 25 for separating and insulating the p-type semiconductor layer 13p and the n-type semiconductor layer 13n from each other is formed. The separation trench 25 makes it difficult for a leakage to occur.

Thereafter, a linear metal electrode layer 18 (18p, 18n) is formed on the transparent electrode layer 17 by using, for example, a mesh screen (not shown) having an opening.

By the steps described above, the backside junction-type solar cell 10 is formed.

### CONCLUSION AND EFFECT

The following can be said from the method for manufacturing a solar cell 10 described above. First, in the step shown in FIG. 8, the lift-off layer LF (see FIG. 7) is removed using an etching solution, thereby removing both of the intrinsic semiconductor layer 12n and the n-type semiconductor layer 13n deposited on this lift-off layer LF from the crystal substrate 11 (so-called lift off). This step does not require a resist coating step and a developing step used in the photolithography performed in the step shown in FIG. 6, for example. Therefore, the n-type semiconductor layer 13n is easily patterned.

Note that, for the lift-off layer LF formed of a plurality of layers, the lift-off layer LF may be formed of three or more layers. However, considering manufacturing cost and productivity, the lift-off layer LF is preferably formed of two layers.

The film thickness of the entire lift-off layers LF is preferably from 20 nm to 600 nm, particularly preferably from 50 nm to 450 nm, in both a case in which the lift-off layer LF is formed of a single layer and a case in which the lift-off layer LF is formed of a plurality of layers. For the lift-off layer LF formed of a plurality of layers, the closest layer to the p-type semiconductor layer 13p is preferably the thinnest within this range.

In one preferred embodiment, the surfaces of the p-type semiconductor layer 13p and the n-type semiconductor layer 13n formed over the backside major surface 11SB of the crystal substrate 11 having a texture structure TX also have a texture structure (second texture structure) reflecting the texture structure TX.

If the conductivity type semiconductor layer 13 has a texture structure TX on its surface, the etching solution easily penetrates into the semiconductor layer 13 by projections and depressions of the texture structure TX. For this reason, the conductivity type semiconductor layer 13 is easily removed, i.e., easily patterned.

In this embodiment, the texture structure TX (first texture structure) is provided to both major surfaces 11S, i.e., the frontside major surface 11SU and the backside major surface 11SB of the crystal substrate 11, but may be provided on either one of them. That is, if the texture structure TX is provided on the frontside major surface 11SU, the effects of collecting and confining of received light are enhanced. On the other hand, if the texture structure TX is provided on the backside major surface 11SB, an effect of collecting light is enhanced, and the conductivity type semiconductor layer 13 is patterned easily. Thus, the texture structure TX may be provided on at least one major surface 11S of the crystal substrate 11. Further, in this embodiment, the texture structures TX on both major surfaces 11S have the same pattern although not limited thereto, but the sizes of the projections and depressions in the texture structure TX may differ between the frontside major surface 11SU and the backside major surface 11SB.

In the step shown in FIG. 6, the backside major surface 11SB of the crystal substrate 11 is exposed at the non-formed area NA although not limited thereto. That is, the intrinsic semiconductor layer 12p may remain on the non-formed area NA of the backside major surface 11SB. It is required that the p-type semiconductor layer 13p is selectively removed, and a region from which the p-type semiconductor layer 13p has been removed is the non-formed area NA.

In this case, the step of forming the intrinsic semiconductor layer 12n prior to the deposition of the n-type semiconductor layer 13n on the remaining lift-off layer LF and non-formed area NA can be omitted.

For example, if the lift-off layer LF is formed of two layers of a first lift-off layer LF1 and a second lift-off layer LF2 stacked in this order, the step shown in FIG. 6 may be performed by forming an opening in the second lift-off layer LF2, bringing the etching solution into contact with the first lift-off layer LF1 through the opening formed, and then removing the layer in contact with the etching solution. The step shown in FIG. 6 may be performed further by removing the lift-off layer LF as mentioned above, bringing the etching solution into contact with the p-type semiconductor layer 13p, and removing the p-type semiconductor layer 13p in contact with the etching solution. The opening may be formed by causing cracks in the lift-off layer LF.

The formation of the opening in the second lift-off layer LF2 and passing the etching solution through the opening allows the etching solution to be reliably in contact with the second lift-off layer LF2 and the first lift-off layer LF1. Therefore, the entire lift-off layer LF is efficiently removed. Further, removing the lift-off layer LF allows the etching solution to be in contact with the p-type semiconductor layer 13p that is covered with the lift-off layer LF, thereby further removing the p-type semiconductor layer 13p.

The technique disclosed herein is not limited to the above-described embodiment, and can be replaced without departing from the spirit and scope of the claims.

For example, in the above embodiment, the p-type semiconductor layer 13p is used as the semiconductor layer in the step shown in FIG. 5 although is not limited thereto, and the n-type semiconductor layer 13n may be used. Further, the conductivity type of the crystal substrate 11 is not particularly limited, and may be either p-type or n-type.

The embodiments described above are illustrative only in every respect, and are not intended to limit the scope of the present disclosure. Modifications and changes belonging to equivalents of claims are all within the scope of the present disclosure.

### EXAMPLES

The examples of the technique according to the present disclosure are described in more detail below. However, the technique according to the present disclosure is not limited to these examples. Solar cells of examples and comparative examples were produced in the following manner (see Table 1).

Crystal Substrate

First, as a crystal substrate, a 200-μm-thick single crystal silicon substrate was employed. Both major surfaces of the single crystal silicon substrate were anisotropically etched. Thus, a pyramidal texture structure was formed on the crystal substrate.

Intrinsic Semiconductor Layer

The crystal substrate was introduced into a CVD device to form, on both major surfaces of the introduced crystal substrate, an intrinsic semiconductor layer (film thickness: 8 nm) made of silicon. The film-forming conditions for the intrinsic semiconductor layer included the substrate temperature of 150° C., the pressure of 120 Pa, the flow rate ratio SiH₄/H₂ of 3/10, and the power density of 0.011 W/cm².

P-type Semiconductor Layer (Semiconductor Layer of First Conductivity Type)

The crystal substrate having the respective intrinsic semiconductor layers formed on both major surfaces was introduced into the CVD device to form a p-type hydrogenated amorphous silicon-based thin film (film thickness: 10 nm) on the intrinsic semiconductor layer on the backside major surface. The film-forming conditions for the p-type hydrogenated amorphous silicon-based layer included the substrate temperature of 150° C., the pressure of 60 Pa, the flow rate ratio SiH₄/B₂H₆ of ⅓, and the power density of 0.01 W/cm². The flow rate of the B₂H₆ gas herein is a flow rate of a diluent gas obtained by diluting B₂H₆ with H₂ to have a B₂H₆ density of 5000 ppm.

Lift-Off Layer

A 200-nm-thick lift-off layer that contains silicon oxide (SiOₓ) as a main component was formed on the p-type hydrogenated amorphous silicon-based thin film using a plasma-enhanced CVD device.

Table 1 shows Examples 1 to 8 and Comparative Examples 1 and 2 in which all film-forming conditions for the lift-off layer were set such that the substrate temperature was 150° C., the pressure was 50 Pa, the flow rate ratio of SiH₄/CO₂/H₂ was 1/10/750, and the power density was 0.15 W/cm².

Patterning of Lift-off Layer and P-type Semiconductor Layer

First, a photosensitive resist film was formed over the backside major surface of the crystal substrate having the formed lift-off layer. The photosensitive lift-off layer formed was exposed to light and developed by photolithography, thereby exposing a region having parts to be removed of the lift-off layer, the p-type semiconductor layer, and the intrinsic semiconductor layer. Then, the crystal substrate having the plurality of layers formed was immersed in hydrofluoric nitric acid containing 1 wt % hydrogen fluoride as an etching agent, thereby removing the lift-off layer. The crystal substrate was rinsed with pure water, and then immersed in ozone-hydrofluoric acid solution obtained by mixing 20 ppm ozone and 5.5 wt % hydrofluoric acid, to remove the parts of the p-type semiconductor layer exposed by the removal of the lift-off layer, and the intrinsic semiconductor layer immediately below the p-type semiconductor layer. Hereinafter, this step is referred to as a patterning step.

N-type Semiconductor Layer (Semiconductor Layer of Second Conductivity Type)

After the first semiconductor layer patterning step, the exposed backside major surface was washed with 2 wt % hydrofluoric acid, and the crystal substrate washed was introduced into the CVD device to form an intrinsic semiconductor layer (film thickness: 8 nm) on and over the backside major surface under the same film-forming conditions as for the intrinsic semiconductor layer for the first time. Then, an n-type hydrogenated amorphous silicon-based layer (film thickness: 10 nm) was formed on the intrinsic semiconductor layer formed. The film-forming conditions for the p-type hydrogenated amorphous silicon-based layer included the substrate temperature of 150° C., the pressure of 60 Pa, the flow rate ratio SiH₄/PH₃ of ½, and the power density of 0.01 W/cm². The flow rate of the PH₃ gas herein is a flow rate of a diluent gas obtained by diluting PH₃ with H₂ to have a PH₃ density of 5000 ppm.

Removal of Lift-Off Layer and n-type Semiconductor Layer

The crystal substrate having the n-type semiconductor layer formed was immersed in 5 wt % hydrofluoric acid (etching solution) containing the liquidity adjusting agent shown in Table 1 to selectively remove the lift-off layer, the n-type semiconductor layer covering the lift-off layer, and the intrinsic semiconductor layer between the lift-off layer and the n-type semiconductor layer together. Hereinafter, this step is referred to as a lift-off step.

After the lift-off step, the crystal substrate was immersed in water containing the liquidity adjusting agent (rinsing liquid) shown in Table 1 to remove the layers remaining after the lift-off step, that is, the lift-off layer, the n-type semiconductor layer covering the lift-off layer, and the intrinsic semiconductor layer between the lift-off layer and the n-type semiconductor layer, and to remove the etching solution. Hereinafter, this step will be referred to as a rinsing step.

Preparation of Etching Solution for Lift-Off Step and Rinsing Liquid for Rinsing Step

The etching solution was a solution containing 5 wt % hydrofluoric acid as a main component. The rinsing liquid contained pure water as a main component. A liquidity adjusting agent shown in Table 1 was added to each of the etching solution and the rinsing liquid. As ethanol, first grade ethanol (manufactured by Wako Pure Chemical Industries, Ltd.) was used. As an aqueous sodium chloride solution, a 15 wt % solution of sodium chloride (manufactured by Wako Pure Chemical Industries, Ltd.) in water was used.

The surface tension of each of the etching solution and the rinsing liquid was monitored in an environment at 25° C., with a dynamic surface tensiometer (manufactured by EKO Instruments Co., Ltd.). The contact angles of the etching solution or the rinsing liquid relative to the lift-off layer, the p-type semiconductor layer, and the n-type semiconductor layer were determined by forming droplets of each liquid on the surface of each layer in an environment at 25° C. and a humidity of 50% and measuring the contact angles with a contact angle meter (CA-X) manufactured by Kyowa Interface Science Co., Ltd. in accordance with the θ/2 method.

The amount of the liquidity adjusting agent added shown in Table 1 was expressed relative to 7 L of the etching solution or the rinsing liquid in terms of vol %.

Electrode Layer and Low Reflection Layer

Using a magnetron sputtering device, an oxide film (film thickness: 100 nm), which was a basis of transparent electrode layers, was formed on the conductivity type semiconductor layer over the crystal substrate. A silicon nitride layer, which is a low reflection layer, was formed over a light-receiving side of the crystal substrate. As a transparent conductive oxide, indium oxide (ITO) containing tin oxide at a concentration of 10 mass % was used. A mixed gas of argon and oxygen was introduced into a chamber of the sputtering device, and the pressure in the chamber was set at 0.6 Pa. A mixing ratio between argon and oxygen was set such that the low refractive index layer had the lowest (bottom) refractive index. Further, the film formation was performed using a DC power source at a power density of 0.4 W/cm².

Then, etching was performed by photolithography such that only the transparent conductive oxide films on the conductivity type semiconductor layer (the p-type semiconductor layer and the n-type semiconductor layer) remained. Thus, transparent electrode layers were formed. By the transparent electrode layers formed by this etching, conduction between a transparent conductive oxide film on the p-type semiconductor layer and a transparent conductive oxide film on the n-type semiconductor layer was inhibited.

A silver paste (DOTITE FA-333 manufactured by Fujikura Kasei Co., Ltd.) without dilution was screen-printed on the transparent electrode layers, which were then subjected to a heat treatment in an oven at 150° C. for 60 minutes. Thus, metal electrode layers were formed.

The evaluation methods for the back-contact type solar cells will be described below. See Table 1 for evaluation results.

Evaluation of Conversion Efficiency

Each of the solar cells was irradiated with reference sunlight of an air mass (AM) 1.5 at a light amount of 100 mW/cm², and the conversion efficiency (Eff (%)) of the solar cell was measured. The maximum value of the conversion efficiency (solar cell characteristic) of Example 1 was set to 1.00, and the result based on the value relative to the maximum value was listed in Table 1.

Specifically, in each of the Examples and the Comparative Examples, ten solar cells were produced. The case in which the number of the solar cells having a relative value of the conversion efficiency of 0.90 or more to 1.00 or less was seven was evaluated as “A,” the case in which the number was four or more to less than seven was evaluated as “B,” and the case in which the number was less than four was evaluated as “C.”

TABLE 1

| | Etching Solution | | | | | | |
|---|---|---|---|---|---|---|---|
| | | | | Contact Angle | Contact Angle | Contact | |
| | | Amount | | Relative to | Relative to | Angle | Rinsing Liquid |
| | Liquidity | to be | Surface | P-type | N-type | Relative | Liquidity |
| | Adjusting | Added | Tension | Semiconductor | Semiconductor | to Lift-off | Adjusting |
| | Agent | (vol %) | (mN/m) | Layer (°) | Layer (°) | Layer (°) | Agent |
| Ex. 1 | Ethanol | 10 | 50 | 55 | 82 | <55 | Ethanol |
| Ex. 2 | Ethanol | 30 | 35 | 40 | 70 | <70 | Ethanol |
| Ex. 3 | Ethanol | 5 | 23 | 55 | 81 | <81 | Ethanol |
| | ↓ | | ↓ | | | | ↓ |
| | Aqueous | | 55 | | | | Aqueous |
| | Sodium | | | | | | Sodium |
| | Chloride | | | | | | Chloride |
| | Solution | | | | | | Solution |
| Ex. 4 | Ethanol | 10 | 50 | 55 | 82 | <55 | Ethanol |
| Ex. 5 | Ethanol | 10 | 50 | 55 | 82 | <55 | Ethanol |
| Ex. 6 | None | — | 74 | 76 | 95 | <95 | None |
| Ex. 7 | Ethanol | 10 | 50 | 55 | 82 | <82 | Ethanol |
| Ex. 8 | Aqueous | 5 | 80 | 86 | 101 | <101 | Aqueous |
| | Sodium | | | | | | Sodium |
| | Chloride | | | | | | Chloride |
| | Solution | | | | | | Solution |
| Comp. | Ethanol | 30 | 35 | 25 | 55 | <55 | Ethanol |
| Ex. 1 | | | ↓ | | | | |
| | | | 23 | | | | |
| Comp. | Ethanol | 50 | 20 | 25 | 55 | <55 | Ethanol |
| Ex. 2 | | | | | | | |

| | Rinsing Liquid | | | | | | |
|---|---|---|---|---|---|---|---|
| | | | Contact Angle | Contact Angle | Contact | | |
| | Amount | | Relative to | Relative to | Angle | | |
| | to be | Surface | P-type | N-type | Relative to | | |
| | Added | Tension | Semiconductor | Semiconductor | Lift-off | Inclination | Solar Cell |
| | (vol %) | (mN/m) | Layer (°) | Layer (°) | Layer (°) | Angle (°) | Characteristic |
| Ex. 1 | 5 | 60 | 62 | 90 | <62 | 65 | A |
| Ex. 2 | 20 | 45 | 50 | 102 | <102 | 65 | A |
| Ex. 3 | 5 | 27 | 65 | 88 | <88 | 65 | A |
| | | ↓ | | | | | |
| | | 60 | | | | | |
| Ex. 4 | 5 | 60 | 62 | 90 | <62 | 55 | A |
| Ex. 5 | 5 | 60 | 62 | 90 | <62 | 70 | A |
| Ex. 6 | — | 73 | 80 | 108 | <108 | 65 | B |
| Ex. 7 | 5 | 60 | 62 | 90 | <90 | 90 | B |
| Ex. 8 | 5 | 82 | 90 | 107 | <107 | 65 | B |
| Comp. | 20 | 45 | 30 | 62 | <62 | 65 | C |
| Ex. 1 | | ↓ | | | | | |
| | | 27 | | | | | |
| Comp. | 50 | 18 | 22 | 49 | <49 | 65 | C |
| Ex. 2 | | | | | | | |

As shown in Table 1, in Example 1, ethanol was added to the etching solution for the lift-off step at a concentration of 10 vol %, and to the rinsing liquid for the rinsing step at a concentration of 5 vol %. The surface tension of the etching solution was 50 mN/m, the contact angle relative to the p-type semiconductor layer was 55°, the contact angle relative to the n-type semiconductor layer was 82°, and the contact angle relative to the lift-off layer was smaller than 55°. The surface tension of the rinsing liquid was 60 mN/m, the contact angle relative to the p-type semiconductor layer was 62°, the contact angle relative to the n-type semiconductor layer was 90°, and the contact angle relative to the lift-off layer was smaller than 62°. At this time, the inclination angle of the average surface of the semiconductor substrate relative to the surfaces of both the etching solution and the rinsing liquid was set to 65°. The semiconductor substrate was immersed in the etching solution for about 3 minutes. The immersion time was the same in Examples 2 to 5. In Example 1, the production yield was 70% or more.

In Example 2, ethanol was added to the etching solution at a concentration of 30 vol %, and to the rinsing liquid for the rinsing step at a concentration of 20 vol %. The surface tension of the etching solution was 35 mN/m, the contact angle relative to the p-type semiconductor layer was 40°, the contact angle relative to the n-type semiconductor layer was 70°, and the contact angle relative to the lift-off layer was smaller than 70°. The surface tension of the rinsing liquid was 45 mN/m, the contact angle relative to the p-type semiconductor layer was 50°, the contact angle relative to the n-type semiconductor layer was 102°, and the contact angle relative to the lift-off layer was smaller than 102°. The inclination angle of the average surface of the semiconductor substrate relative to the liquid surface was 65°, which was the same as in Example 1. In Example 2 as well, the production yield was 70% or more.

In Example 3, fifty or more solar cells were treated under the conditions of Example 2. When the surface tension of the etching solution decreased to 23 mN/m, and the surface tension of the rinsing liquid decreased to 27 mN/n (Comparative Example 1), an aqueous sodium chloride solution was added. The aqueous sodium chloride solution was added to the etching solution and the rinsing liquid at a concentration of 5 vol %. The surface tension of the etching solution to which the inorganic salt had been added was restored to 55 mN/m, the contact angle relative to the p-type semiconductor layer was 55°, and the contact angle relative to the n-type semiconductor layer was 81°. The contact angle of the etching solution relative to the lift-off layer was smaller than 81°. Further, the surface tension of the rinsing liquid was restored to 60 mN/m, the contact angle relative to the p-type semiconductor layer was 65°, and the contact angle relative to the n-type semiconductor layer was 88°. The contact angle of the rinsing liquid relative to the lift-off layer was smaller than 88°.

In Comparative Example 1 in which the treatment continued as in Example 2, the contact angle of the etching solution relative to the p-type semiconductor layer was 25°, the contact angle relative to the n-type semiconductor layer was 55°, and the contact angle relative to the lift-off layer was smaller than 55°. The contact angle of the rinsing liquid relative to the p-type semiconductor layer was 30°, the contact angle relative to the n-type semiconductor layer was 62°, and the contact angle relative to the lift-off layer was smaller than 62°. In Comparative Example 1, the production yield was less than 4%. It is considered because in Comparative Example 1, the decrease in the surface tension of each of the etching solution and the rinsing liquid caused reattachment of the lift-off layer peeled off by the lift-off and the n-type semiconductor layer and the intrinsic semiconductor layer covering the lift-off layer to the semiconductor substrate.

In Examples 4 and 5, the amounts of the liquidity adjusting agent added to the etching solution and the rinsing liquid were the same as those in Example 1. The inclination angle of the average surface of the semiconductor substrate relative to the surfaces of both the etching solution and the rinsing liquid was set to 55° in Example 4 and to 70° in Example 5. In Examples 4 and 5, the production yield was 70% or more.

In Example 6, the lift-off and the rinsing were performed without using a liquidity adjusting agent. The other conditions were the same as those in Example 1. In Example 6, the surface tension of the etching solution was 74 mN/m, the contact angle relative to the p-type semiconductor layer was 76°, the contact angle relative to the n-type semiconductor layer was 95°, and the contact angle relative to the lift-off layer was smaller than 95°. The surface tension of the rinsing liquid was 73 mN/m, the contact angle relative to the p-type semiconductor layer was 80°, the contact angle relative to the n-type semiconductor layer was 108°, and the contact angle relative to the lift-off layer was smaller than 108°. In Example 6, the semiconductor substrate was immersed in the etching solution for 7 minutes. The yield was 40%, which was lower than those of Examples 1 to 5. It is considered because, in Example 6, the excessive immersion of the solar cells in hydrofluoric acid damaged the solar cells, as compared with Examples 1 to 5. It is further considered that observed some fine peeled particles (of the lift-off layer and the n-type and intrinsic semiconductor layer covering the lift-off layer) floating on the liquid surface and in the liquid were reattached to the semiconductor substrate, thereby reducing the solar cell performance.

In Example 7, the solar cell was introduced into the etching solution or the rinsing liquid at an inclination angle relative to the etching solution or the rinsing liquid of 90° (right angle). Except for the inclination angle, the other conditions were the same as those in Example 1. The yield was about 50%. In Example 7, the lift-off layer peeled off during the lift-off step and the rinsing step and the n-type and intrinsic semiconductor layers covering the lift-off layer were more easily reattached to the semiconductor substrate than Examples 1 to 5. This is considered to be the cause of reduction in the solar cell performance.

In Example 8, the surface tension was increased as compared to Examples 1 to 5, by reducing the amount of the liquidity adjusting agent added. Specifically, an aqueous sodium chloride solution was added to the etching solution of Example 8 at a concentration of 5 vol %, and to the rinsing liquid at a concentration of 5 vol %. The surface tension of the etching solution was 80 mN/m, the contact angle relative to the p-type semiconductor layer was 86°, the contact angle relative to the n-type semiconductor layer was 101°, and the contact angle relative to the lift-off layer was smaller than 101°. The surface tension of the rinsing liquid was 82 mN/m, the contact angle relative to the p-type semiconductor layer was 90°, the contact angle relative to the n-type semiconductor layer was 107°, and the contact angle relative to the lift-off layer was smaller than 107°. In Example 8, the yield was 40%.

It was inferred that, in Example 8, the wettability of the etching solution was low due to the large surface tension, which in some cases results in insufficient etching of the lift-off layer. It was further considered that the insufficient etching caused the “undissolved residue” of the lift-off layer to remain on the surface of the p-type semiconductor layer, and the undissolved residue serving as a resistance reduced the solar cell performance

In Comparative Example 2, the surface tension was minimized by adding an excessive amount of the liquidity adjusting agent. Specifically, ethanol was added to the etching solution of Comparative Example 2 at a concentration of 50 vol %, and to the rinsing liquid at a concentration of 50 vol %. The surface tension of the etching solution was 20 mN/m, the contact angle relative to the p-type semiconductor layer was 25°, the contact angle relative to the n-type semiconductor layer was 55°, and the contact angle relative to the lift-off layer was smaller than 55°. The surface tension of the rinsing liquid was 18 mN/m, the contact angle relative to the p-type semiconductor layer was 22°, the contact angle relative to the n-type semiconductor layer was 49°, and the contact angle relative to the lift-off layer was smaller than 49°. In Comparative Example 2, the yield was 20%. It was inferred that, in Comparative Example 2, the wettability of the etching solution was high due to the small surface tension, which caused an excessive contact of hydrofluoric acid with the solar cell and heavily damaged the solar cell.

As described above, the contact angle of the etching solution or the rinsing liquid relative to the n-type semiconductor layer is 65° or more to 110° or less, particularly preferably 70° or more to 105° or less.

The surface tension of each of the etching solution and the rinsing liquid is preferably 25 mN/m or more to 85 mN/m or less, more preferably 25 mN/m or more to 70 mN/m or less, particularly preferably 30 mN/m or more to 60 mN/m or less.

### Second Embodiment

Hereinafter, a second embodiment of the present disclosure will be described with reference to the drawings.

FIG. 10 illustrates a substrate holder according to the second embodiment. As shown in FIG. 10, the substrate holder 40 according to this embodiment includes, for example, a casing 41 having a rectangular shape. The substrate holder 40 is used for conveying the semiconductor substrate 11 between the producing steps and used for the lift-off step, the rinsing step, and a drying step, for example, with a plurality of semiconductor substrates 11 housed in the substrate holder 40. The casing 41 of the substrate holder 40 is provided with a housing portion 43 housing a plurality of supports 42. The bottom surface of each support 42 is inclined at an angle θ relative to a bottom surface of the casing 41. As described above, the inclination angle θ is preferably 30°<0<70°. The semiconductor substrates 11 are one by one inserted to and housed in the respective supports 42, and housed in the housing portion 43. Note that, in this embodiment, the supports 42 has a five-tier configuration, but this is merely an example, and the number of tiers may be appropriately changed according to the scale of the manufacturing facility. The substrate holder 40 is brought into contact with the etching solution or the rinsing liquid with the bottom surface of the casing 41 of the substrate holder 40 being horizontal.

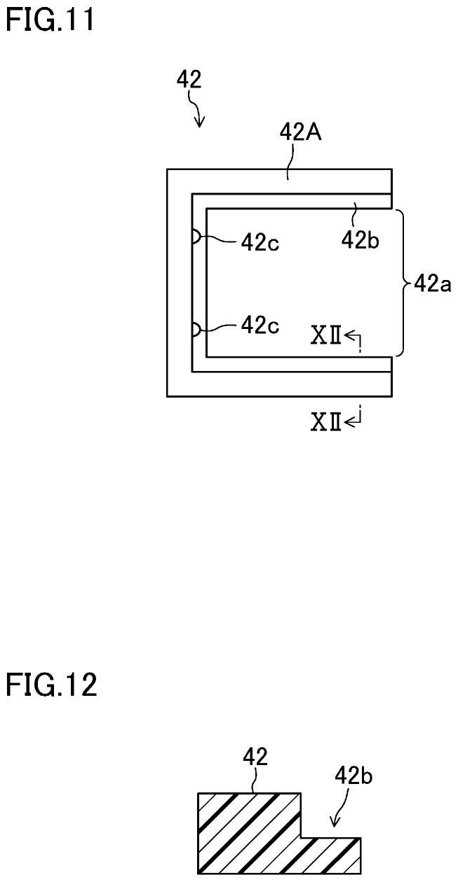

As shown in FIG. 11, the supports 42 are formed of, for example, a bar member 42A having a U-shape in a plan view. The semiconductor substrate 11 is inserted from an opening 42a (opening portion) in the U-shape of the bar member 42A. At this time, the semiconductor substrates 11 inserted into the respective supports 42 come into contact with the surface of the liquid with the backside major surface 11SB, i.e., the surface on which the lift-off layer LF has been formed facing upward, as described above. The casing 41 has openings 42a and openings through which the liquid flows in at least the bottom surface and the upper surface of the casing 41.

FIG. 12 is a cross-sectional view taken along line XII-XII of FIG. 11. As shown in FIG. 12, a peripheral portion of an upper surface of the bar member 42A is provided with a step 42b to be in contact with a peripheral portion of a lower surface of the semiconductor substrate 11. The step 42b guides an outer peripheral surface of the semiconductor substrate 11 to reach the bar connecting facing portions of the U-shape in the bar member 42A, i.e., reaches the bar located at the bottom of the U-shape. In the actual manufacturing process, when a conveying device inserts the semiconductor substrates 11 into the respective supports 42 of the holder 40, a rear side of the casing 41 is lifted by an angle θ relative to a front side of the casing 41 so that the supports 42 are kept inclined so as to be horizontal relative to a floor surface. Thus, a typical conveying device may be used.

Further, the bar located at the bottom of the U-shape of each bar member 42A may be provided with a protrusion 42c for supporting an upper surface of the semiconductor substrate 11 between the bar member 42A and the step 42b. With this configuration, the semiconductor substrates 11 supported by the respective supports 42 in the substrate holder 40 come into contact with the liquid with being inclined by the angle θ relative to the liquid surface. Thus, portions of the semiconductor substrates 11 that first come into contact with the liquid (the portions on the left side of the casing 41 shown in FIG. 10) are pushed up by the liquid and tends to float. This may result in displacement of the semiconductor substrates 11 from the supports 42. In this embodiment, at least one protrusion 42c provided to each support 42 retains the upper surface of the portion of the semiconductor substrate 11 that first comes into contact with the liquid. This avoids displacement of the semiconductor substrates 11 from the supports 42 at the time of coming into contact with the liquid.

Note that the supports 42 may be configured to be pulled out or removed from the housing portion 43. Further, the casing 41 and the supports 42 of the substrate holder 40 may be formed of, for example, a rigid resin material which is resistant to acid.

What is claimed is:

1. A method for manufacturing a solar cell, comprising:
forming a first semiconductor layer of a first conductivity type on one of two major surfaces on a semiconductor substrate, the two major surfaces facing each other;
forming a lift-off layer on the first semiconductor layer;
selectively removing the lift-off layer and the first semiconductor layer;
forming a second semiconductor layer of a second conductivity type on the major surface having the lift-off layer and the first semiconductor layer;
removing the second semiconductor layer covering the lift-off layer by removing the lift-off layer using an etching solution; and
washing the semiconductor substrate by using a rinsing liquid; wherein
a contact angle of the etching solution or the rinsing liquid relative to the lift-off layer is smaller than a contact angle of the etching solution or the rinsing liquid relative to the second semiconductor layer, and
the contact angle of the etching solution or the rinsing liquid relative to the second semiconductor layer is 65° or more to 110° or less.

2. The method of claim 1, wherein
a surface tension of the etching solution or the rinsing liquid is 25 mN/m or more to 85 mN/m or less.

3. The method of claim 1, wherein
the second semiconductor layer is made of amorphous silicon.

4. The method of claim 1, wherein
the first semiconductor layer and the second semiconductor layer are made of amorphous silicon, and
when a contact angle of the rinsing liquid or the etching solution relative to the first semiconductor layer is represented by θ1, and the contact angle of the rinsing liquid or the
etching solution relative to the second semiconductor layer is represented by θ2, a relational expression θ1<θ2 is satisfied.

5. The method of claim 1, wherein
the lift-off layer is made of silicon oxide, and
the etching solution contains hydrofluoric acid, and further contains a liquidity adjusting agent for adjusting the surface tension of liquid.

6. The method of claim 5, wherein
the liquidity adjusting agent is a lower alcohol or an inorganic salt.

7. The method of claim 1, wherein
the rinsing liquid contains water as a main component, and further contains a liquidity adjusting agent.

8. The method of claim 7, wherein
the liquidity adjusting agent is a lower alcohol or an inorganic salt.

9. The method of claim 1, wherein
when the semiconductor substrate comes into contact with the etching solution or the rinsing liquid, performed is an inclination contact of bringing the semiconductor substrate into contact with at least one of the etching solution or the rinsing liquid with the semiconductor substrate being inclined relative to a liquid surface of the at least one of the etching solution or the rinsing liquid.

10. The method of claim 9, wherein
in the inclination contact, an angle of the semiconductor substrate with the liquid surface is 30° or more to 70° or less.

11. The method of claim 1, wherein
a texture structure constituting an uneven surface is formed on at least one of the two major surfaces of the semiconductor substrate.

12. The method of claim 9, wherein
the inclination contact is performed with the one major surface having the lift-off layer in the semiconductor substrate facing upward.

13. A holder to be used in the method of claim 9, the holder comprising:
a casing having a housing portion for housing the semiconductor substrate, wherein
the housing portion includes at least one support for supporting one semiconductor substrate, and
a bottom surface of the support is inclined relative to a bottom surface of the casing to perform the inclination contact.

14. The holder of claim 13, wherein
the support is a bar member having a U-shape in a plan view,
the semiconductor substrate is inserted from an opening in the U-shape of the bar member,
an upper peripheral edge portion of the bar member is provided with a step that comes into contact with a lower peripheral portion of the semiconductor substrate, and
the bar member is provided with a protrusion between the bar member and the step, the protrusion being for supporting an upper surface of the semiconductor substrate.
